(19) United States
(12) Patent Application Publication
(10) Pub. No.: US 2013/0113062 A1
(43) Pub. Date: May 9, 2013

(54) Lens Holder, Method for Manufacturing the Same and Image Capturing Device Thereof

(71) Applicants: Tsung-Ken Yang, Hemei Township (TW); Jen-Te Wang, New Taipei City (TW)

(72) Inventors: Tsung-Ken Yang, Hemei Township (TW); Jen-Te Wang, New Taipei City (TW)

(73) Assignee: ALTEK CORPORATION, Hsinchu (TW)

(21) Appl. No.: 13/342,682

(22) Filed: Jan. 3, 2012

(30) Foreign Application Priority Data
Nov. 3, 2011 (TW) 100140048

(51) Int. Cl. H01L 31/0232; H01L 31/18

(52) U.S. Cl. 257/432; 438/65; 257/E31.127; 257/E31.11

(57) ABSTRACT

A lens holder, a method for manufacturing the same and an image capturing device thereof. The lens holder comprises a hollow substrate, a filter, a hollow elastomer and a photodetector module. The hollow substrate comprises a photodetector accommodating space and a plurality of fixing mechanisms disposed around the photodetector accommodating space. The filter is disposed inside the photodetector accommodating space and covers a hollow section of the hollow substrate. The hollow elastomer is disposed on the filter. The photodetector module is disposed on the hollow elastomer and comprises a photodetector and a substrate. The substrate can be fixed onto the hollow substrate through the plurality of fixing mechanisms. Wherein, a plurality of protrusion parts extends from the hollow elastomer for holding the substrate. The aforementioned lens holder structure can be used to perform a tilt alignment of the photodetector efficiently.

### CROSS-REFERENCE TO RELATED APPLICATION

This application claims the benefit of priority to Taiwan Patent Application No. 100140048, filed on Nov. 3, 2011, in the Taiwan Intellectual Property Office, the disclosure of which is incorporated herein in its entirety by reference.

### BACKGROUND OF THE INVENTION

1. Field of the Invention

The present invention relates to a lens holder, a method of manufacturing the same and an image capturing device thereof, in particular to the lens holder and the method of manufacturing the same capable of performing a photodetector tilt alignment accurately without using any structure of a spring and a washer.

2. Description of the Related Art

Photodetectors, such as charge-coupled devices (CCD) and complementary metal-oxide-semiconductors (CMOS), are used extensively in electronic products having an image capturing function such as a digital camera. During assembly of the electronic device, the photodetector is combined with a carrying substrate, and fixed onto a lens holder by fixing mechanisms. However, the lens holder needs a structure for executing a photodetector tilt alignment to make sure that photodetector is vertical to optical axis of lens. Therefore, at least one spring is usually disposed on a substrate of the lens holder, and at lease one washer is added to the fixing mechanism for fixing the carrying substrate, so that the lens holder of cameras can execute the photodetector tilt alignment.

With reference to FIG. 1 for a schematic view of a conventional lens holder, an IR cut filter is generally disposed at a hollow section of a CCD accommodating space 10 of the lens holder 1. Furthermore, a rubber is disposed at the top of the IR cut filter, and finally a CCD substrate with CCD is fixed onto the lens holder 1 by fixing mechanisms 11. The rubber is provided for fixing the IR cut filter and maintaining a constant distance between the IR cut filter and the CCD.

In FIG. 1, for executing a CCD tilt alignment on the lens holder 1, the fixing mechanism 11 includes a washer 12 disposed thereon, and the periphery of the CCD accommodating space 10 has a plurality of springs 13 disposed thereon. Since the spring 13 must be fixed by using UV glue, it is difficult to rework the spring 13 after the spring 13 is fixed and some technical issues may arise during the assembling process. In addition, the way of using the washer 12 for the alignment will make the adjustment more complicated, and it is difficult to control the thickness of the washer 12 so that the accuracy of the alignment may be affected. Furthermore, the installation of the spring 13 and the washer 12 in the lens holder 1 also causes a higher production cost of the lens holder 1. Therefore, it is an important issue for related manufacturers to develop a lens holder that can achieve the effects of lowering the production cost, simplifying the photodetector tilt alignment procedure, improving the accuracy of the alignment, facilitating the rework, and avoiding technical issues occurred in the assembling process.

### SUMMARY OF THE INVENTION

In view of the aforementioned problems of the prior art, it is a primary objective of the present invention to provide a lens holder, a method of manufacturing the same and an image capturing device thereof to overcome the problems of the conventional lens holder incurring a higher production cost, a more complicated photodetector tilt alignment procedure, a lower alignment accuracy, and a more difficult rework as well as causing technical issues in the assembling process.

To achieve the aforementioned objective, the present invention provides a lens holder, comprising: a hollow substrate, having a lens cavity extended along a side of the hollow substrate, and a photodetector accommodating space extended from the other side of the hollow substrate opposite to the lens cavity, and a plurality of fixing mechanisms disposed around the photodetector accommodating space; a filter, disposed in the photodetector accommodating space, and covered onto a hollow section of the hollow substrate; a hollow elastomer, disposed at a top of the filter, and the hollow section of the hollow elastomer corresponding to the filter; and a photodetector module, disposed at a top of the hollow elastomer, and comprising a photodetector and a substrate, and the photodetector being disposed at a position corresponding to the hollow section of the hollow elastomer, and the substrate being fixed onto the hollow substrate through the plurality of fixing mechanisms; wherein, the hollow elastomer has a plurality of protruding parts extended from a periphery of the hollow elastomer, and the plurality of protruding parts supports the substrate, so that the hollow elastomer can execute a tilt alignment of the photodetector directly.

To achieve the aforementioned objective, the present invention further provides an image capturing device, comprising a lens and a lens holder, and the lens holder comprises: a hollow substrate, having a lens cavity extended along a side of the hollow substrate, and a photodetector accommodating space extended from the other side of the hollow substrate opposite to the lens cavity, and a plurality of fixing mechanisms disposed around the photodetector accommodating space, and the lens cavity being provided for accommodating the lens; a filter, disposed in the photodetector accommodating space, and covered onto a hollow section of the hollow substrate; a hollow elastomer, disposed at a top of the filter, and the hollow section of the hollow elastomer corresponding to the filter; and a photodetector module, disposed at a top of the hollow elastomer, and comprising a photodetector and a substrate, and the photodetector being disposed at a position corresponding to the hollow section of the hollow elastomer, and the substrate being fixed onto the hollow substrate through the plurality of fixing mechanisms; wherein, the hollow elastomer has a plurality of protruding parts extended from a periphery of the hollow elastomer, and the plurality of protruding parts supports the substrate, so that the hollow elastomer can execute a tilt alignment of the photodetector directly.

To achieve the aforementioned objective, the present invention further provides a lens holder manufacturing method, comprising the steps of: forming a hollow substrate; forming a lens cavity on a side of the hollow substrate; forming a photodetector accommodating space on the other side of the hollow substrate, and forming a plurality of fixing mechanisms around the photodetector accommodating space; disposing a filter in the photodetector accommodating space, and covering a hollow section of the hollow substrate; forming a hollow elastomer, and the hollow elastomer having a plurality of protruding parts extended from a periphery of the hollow elastomer; disposing the hollow elastomer to a top of the filter, and the hollow section of the hollow elastomer corresponding to the filter; and disposing a photodetector module on a top of the hollow elastomer, and a photodetector of the photodetector module corresponding to the hollow section of the hollow elastomer, and fixing a substrate of the photodetector module onto the hollow substrate through the plurality of fixing mechanisms, such that the plurality of protruding parts can support the substrate.

Wherein, a quantity of the fixing mechanisms is equal to a quantity of the protruding parts.

Wherein, the quantity of the fixing mechanisms and the protruding parts is 3, 4 or 5.

Wherein, the protruding part is disposed at a position corresponding to the fixing mechanism.

Wherein, any two of the adjacent protruding parts have a constant distance apart.

Wherein, the hollow elastomer is made of rubber.

In summation of the description above, the lens holder, the method of manufacturing the same and the image capturing device thereof in accordance with the present invention have one or more of the following advantages:

(1) The lens holder, the method of manufacturing the same, and the image capturing device thereof do not require adding a washer and a spring in the lens holder, so that the production cost of the lens holder can be lowered significantly.

(2) The lens holder, the method of manufacturing the same, and the image capturing device thereof do not require using UV glue to fix the spring in the lens holder, so that technical issues do not occur easily in the assembling process and it is easy to rework.

(3) The lens holder, the method of manufacturing the same, and the image capturing device thereof use the specially structured rubber to substitute the conventional washer and spring of the lens holder to simplify the alignment procedure, so that a high accuracy can be achieved without the washer.

### BRIEF DESCRIPTION OF THE DRAWINGS

FIG. 1 is a schematic view of a conventional lens holder;

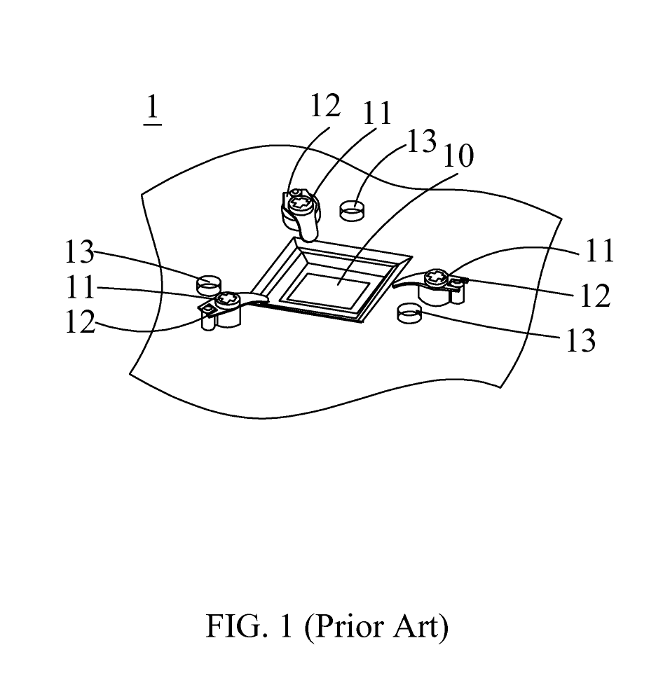

FIG. 2 is a cross-sectional view of a lens holder in accordance with a first preferred embodiment of the present invention;

FIG. 3 is a top view of a lens holder in accordance with the first preferred embodiment of the present invention;

FIG. 4 is a bottom view of a hollow elastomer of a lens holder in accordance with the first preferred embodiment of the present invention;

FIG. 5 is a cross-sectional view of a lens holder in accordance with a second preferred embodiment of the present invention;

FIG. 6 is a top view of a lens holder in accordance with the third preferred embodiment of the present invention;

FIG. 7 is a bottom view of a hollow elastomer of a lens holder in accordance with the third preferred embodiment of the present invention;

FIG. 8 is a schematic view of a lens holder in accordance with a third preferred embodiment of the present invention; and

FIG. 9 is a flow chart of a method of manufacturing a lens holder in accordance with the present invention.

### DETAILED DESCRIPTION OF THE PREFERRED EMBODIMENTS

The technical characteristics of the present invention will become apparent with the detailed description of the preferred embodiments accompanied with the illustration of related drawings as follows. It is noteworthy to point out that the drawings are provided for the purpose of illustrating the present invention, but they are not necessarily drawn according to the actual scale, or are intended for limiting the scope of the invention.

The lens holder of the present invention can be applied to any image capturing device, such as a digital camera, a digital camcorder, a phone with camera or any electronic device with an image capturing function. The digital camera is used as an example in the following preferred embodiments for illustrating the technical characteristics of the present invention, but not intended for limiting the scope of the invention.

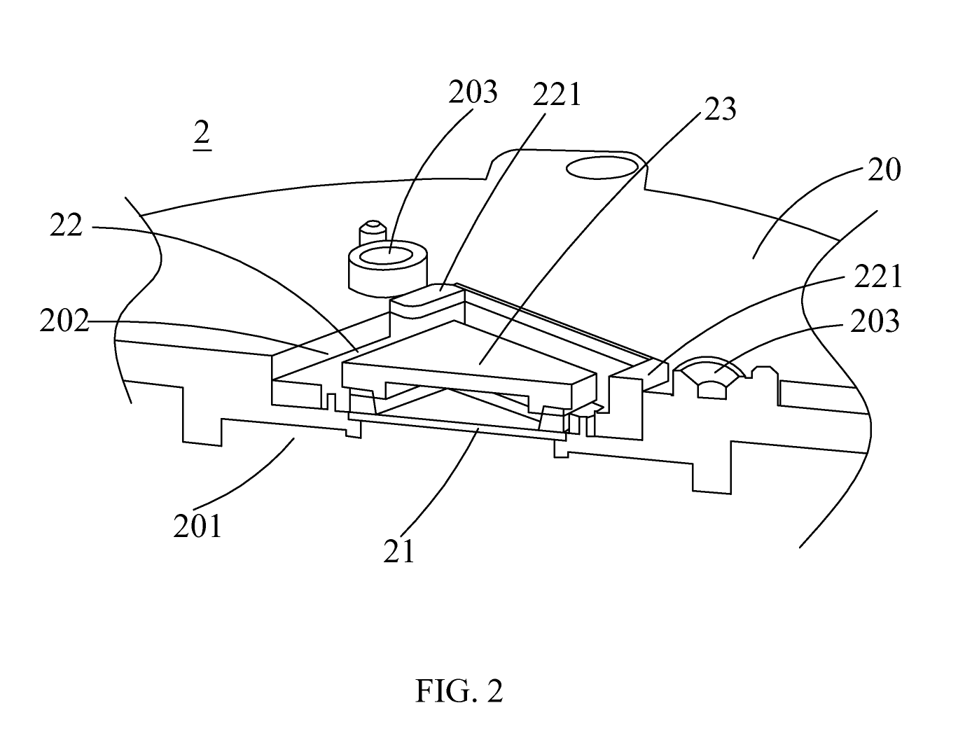

With reference to FIG. 2 for a cross-sectional view of a lens holder in accordance with the first preferred embodiment of the present invention, the lens holder 2 comprises a hollow substrate 20, a filter 21, a hollow elastomer 22 and a photodetector module. Wherein, a lens cavity 201 is extended from a side of the hollow substrate 20 for carrying a lens, and a photodetector accommodating space 202 is extended from the other side of the hollow substrate 20 for accommodating a photodetector 23. Furthermore, a plurality of fixing mechanisms 203 is disposed around a periphery of the photodetector accommodating space 202.

The filter 21 is disposed in the photodetector accommodating space 202, and covered onto a hollow section of the hollow substrate 20 as shown in FIG. 2, wherein the filter 21 can be an IR cut filter, etc. A hollow elastomer 22 is disposed at a top of the filter 21, and the hollow section of the hollow elastomer 22 is corresponding to the filter 21. The hollow elastomer 22 is made of an elastic material such as rubber, etc.

The photodetector module comprises a photodetector 23 and a substrate (not shown in the figure). The photodetector 23 is disposed at a position corresponding to the hollow section of the hollow elastomer 22, and the hollow elastomer 22 can separate the photodetector 23 with the filter 21, such that a constant distance is maintained between the two. The substrate corresponding to the photodetector 23 can be fixed onto the hollow substrate 20 through a plurality of fixing mechanisms 203. In general, the photodetector 23 can be a charge-coupled device (CCD), a complementary metal-oxide-semiconductor (CMOS), etc.

It is noteworthy to point out that a plurality of protruding parts 221 is extended from a periphery of the hollow elastomer 22, and the plurality of protruding parts support a substrate corresponding to the photodetector 23. Since the hollow elastomer 22 has stretchable and contractible properties, therefore the hollow elastomer 22 can be used to directly substitute the conventional spring to execute a tilt alignment of the photodetector 23.

It is noteworthy to point out that there may be a size discrepancy when the lens holder 2 and the lens are produced, and errors may occur during the packaging process of the photodetector 23. In addition, the substrate corresponding to the photodetector 23 is fixed to the fixing mechanisms such as a thread block by passing screws through screw holes on the substrate. However, the substrate corresponding to the photodetector 23 includes electronic circuits with different thicknesses near each holes formed on the substrate, so that errors may also be produced. Due to all kinds of the aforementioned errors, the lens holder 2 requires a special mechanical design for performing the tilt alignment of the photodetector 23 to correct the aforementioned errors.

In the conventional lens holder, a plurality of springs is disposed around the periphery of the photodetector accommodating space, and the stretchable and contractible properties of the spring are used for executing the tilt alignment of the photodetector. Since the springs are fixed onto the hollow substrate by using UV glue, reworking will become difficult, and technical issues will arise in the assembling process. In addition, the conventional lens holder requires the use of a washer to execute the tilt alignment of the photodetector, but the thickness of the washer is difficult to control, and the use of washer for the adjustment involves a more complicated procedure and incurs a higher level of difficulty for the alignment that may affect the correction accuracy. In addition, both spring and washer cause a significantly higher production cost of the lens holder.

The lens holder 2 of the present invention just skillfully changes the shape of the hollow elastomer 22 to allow the lens holder 2 to accurately execute the tilt alignment of the photodetector 23 and facilitate reworking. Since it is not necessary to use the spring anymore, the technical issues occurred during the assembling process can be avoided to further lower the production cost of the lens holder 2. Obviously, the present invention can overcome the shortcomings of the prior art effectively.

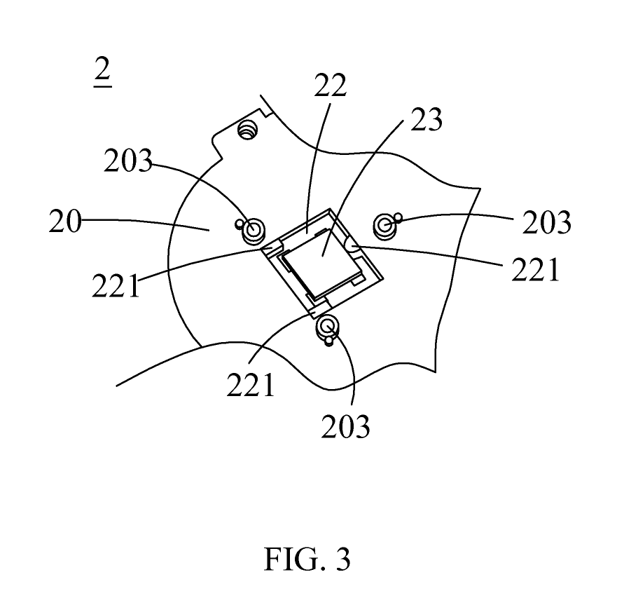

With reference to FIG. 3 for a top view of a lens holder in accordance with the first preferred embodiment of the present invention, the lens holder 2 comprises three fixing mechanisms 203. The substrate (not shown in the figure) of the photodetector 23 is fixed onto the hollow substrate 20 through the fixing mechanisms 203, and there are three protruding parts 221 formed around the periphery of the hollow elastomer 22 and supported the substrate corresponding to the photodetector 23. Since the hollow elastomer 22 has the stretchable and contractible properties, the hollow elastomer 22 can fully substitute the conventional spring.

In FIG. 3, it is obvious that the quantity of the protruding parts 221 and the quantity of the fixing mechanisms 203 are both equal to three, and the protruding parts 221 are disposed at positions corresponding to the fixing mechanisms 203, and such design facilitates executing the tilt alignment of the photodetector 23. Of course, the quantity of the protruding parts 221 and the quantity of the fixing mechanisms 203 can be adjusted according to the actual needs, and not limited to the aforementioned arrangements only.

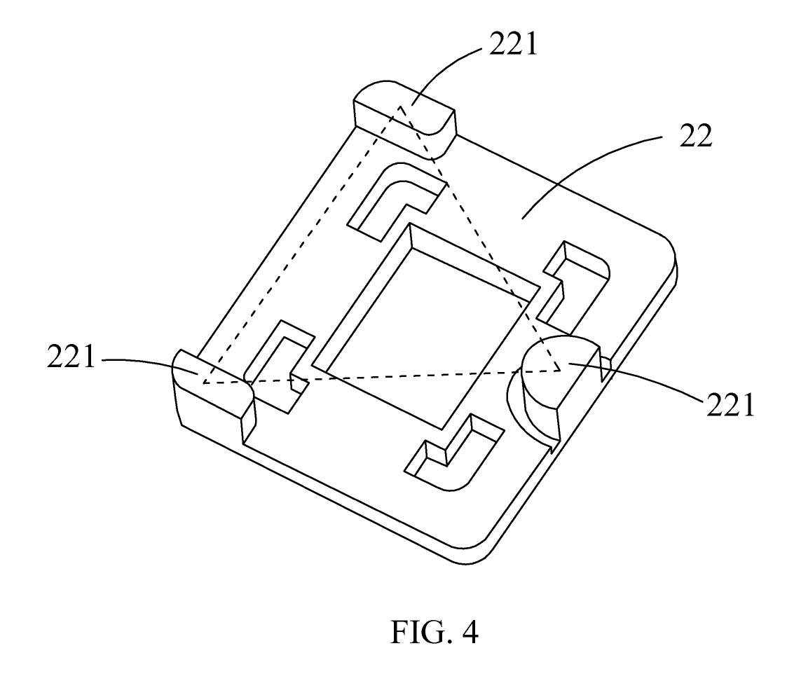

With reference to FIG. 4 for a bottom view of a hollow elastomer of a lens holder in accordance with the first preferred embodiment of the present invention, three protruding parts 221 are extended from a periphery of the rectangular hollow elastomer 22. Preferably, any two of these three protruding parts 221 have a constant distance apart to facilitate executing the tilt alignment of the photodetector. Of course, the shape of the hollow elastomer 22 can be changed according to the actual requirements, and not limited to the aforementioned shape only.

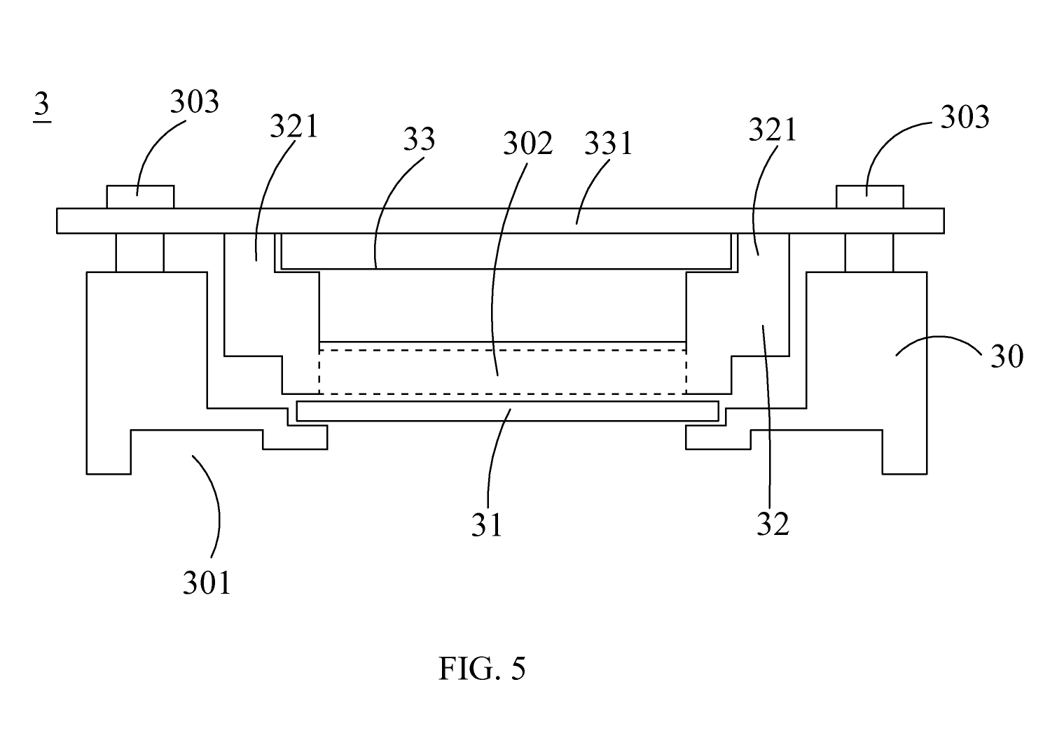

With reference to FIG. 5 for a cross-sectional view of a lens holder in accordance with the second preferred embodiment of the present invention, the lens cavity 301 formed at the bottom of the lens holder 3 is used for accommodating a lens (not shown in the figure). The substrate 331 of the CCD 33 disposed in the photodetector accommodating space 302 can be fixed onto the hollow substrate 30 through fixing mechanisms 303 comprising a screw and a thread block. The hollow rubber 32 is disposed between the IR cut filter 31 and the CCD 33. The CCD 33 can receive the light projected through the lens and the IR cut filter 31.

The conventional hollow rubber is just used for separating the CCD 33 from the IR cut filter 31, so that a constant distance is maintained between the two. The hollow rubber 32 of the present invention also has the same function, but the structure is changed skillfully, and the design of the protruding part 321 is added to the hollow rubber 32 of the present invention. In the figure, it is obvious that the protruding parts 321 support the substrate 331, so that users can make use of the stretchable and contractible properties of the hollow rubber 32 to execute the CCD tilt alignment, and thus the hollow rubber 32 can substitute the conventional spring.

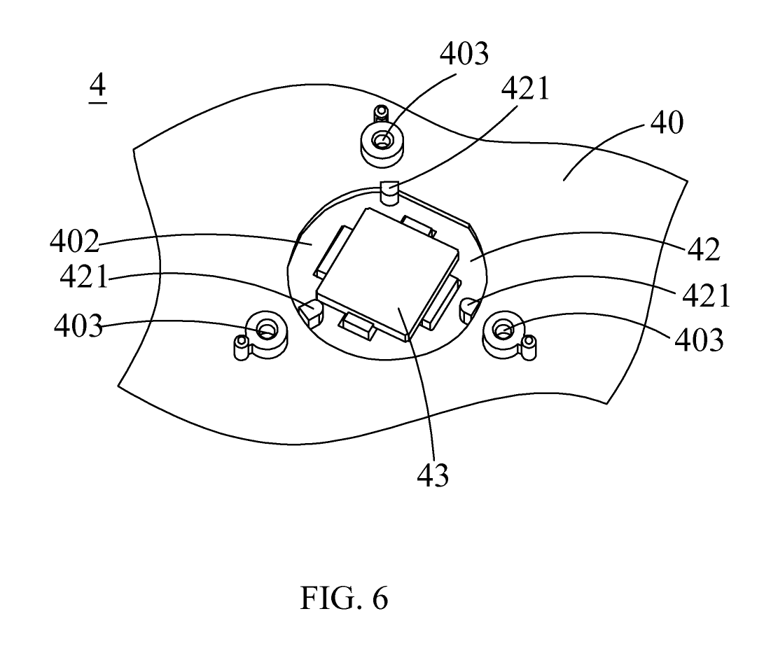

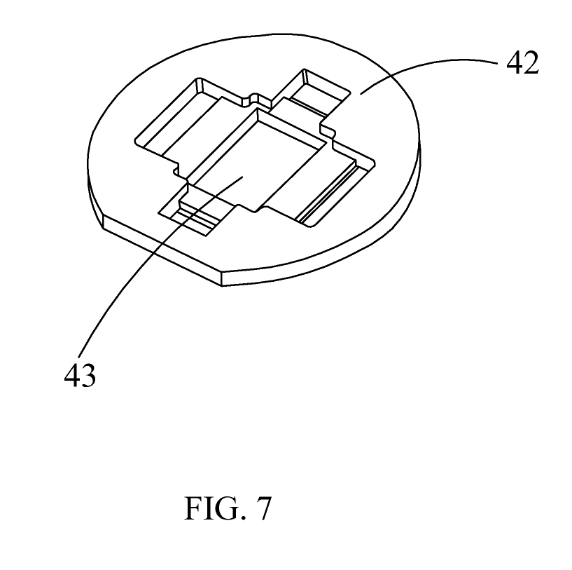

With reference to FIGS. 6 and 7 for the top and bottom views of a lens holder in accordance with the third preferred embodiment of the present invention respectively, a major difference between the lens holder 4 of this preferred embodiment and that of the first preferred embodiment resides on that the shape of the photodetector accommodating space 402 of the hollow substrate 40 is not a perfect circle, and the shape of the hollow elastomer 42 is also not a perfect circle.

Same as the first preferred embodiment, the photodetector 43 of this preferred embodiment is disposed at a position corresponding to the hollow section of the hollow elastomer 42. The substrate (not shown in the figure) corresponding to the photodetector 43 is fixed onto the hollow substrate 40 through three fixing mechanisms 403, and three protruding parts 421 are extended from the periphery of the hollow elastomer 42 and supported the substrate corresponding to the photodetector 43. Similarly, the protruding part 421 is disposed at a position corresponding to the fixing mechanism 403 to achieve a better effect.

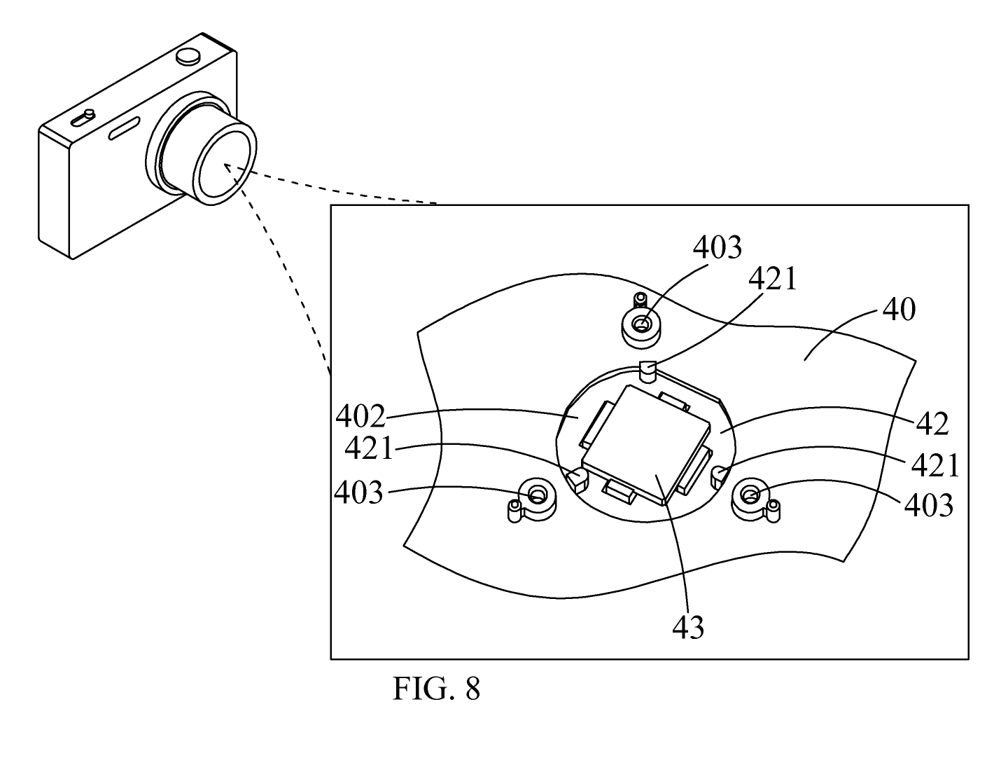

With reference to FIG. 8 for a schematic view of a lens holder in accordance with the third preferred embodiment of the present invention, the lens holder of the present invention can be applied to different types of image capturing devices such as a digital camera, etc. The skillful design of the lens holder of the present invention can lower the production cost of products such as the digital camera, while improving the quality and competitiveness of the products.

Even though the concept of the method of manufacturing a lens holder of the present invention has been described in the section of describing the lens holder of the present invention already, a flow chart is provided for illustrating the present invention as follows for clarity.

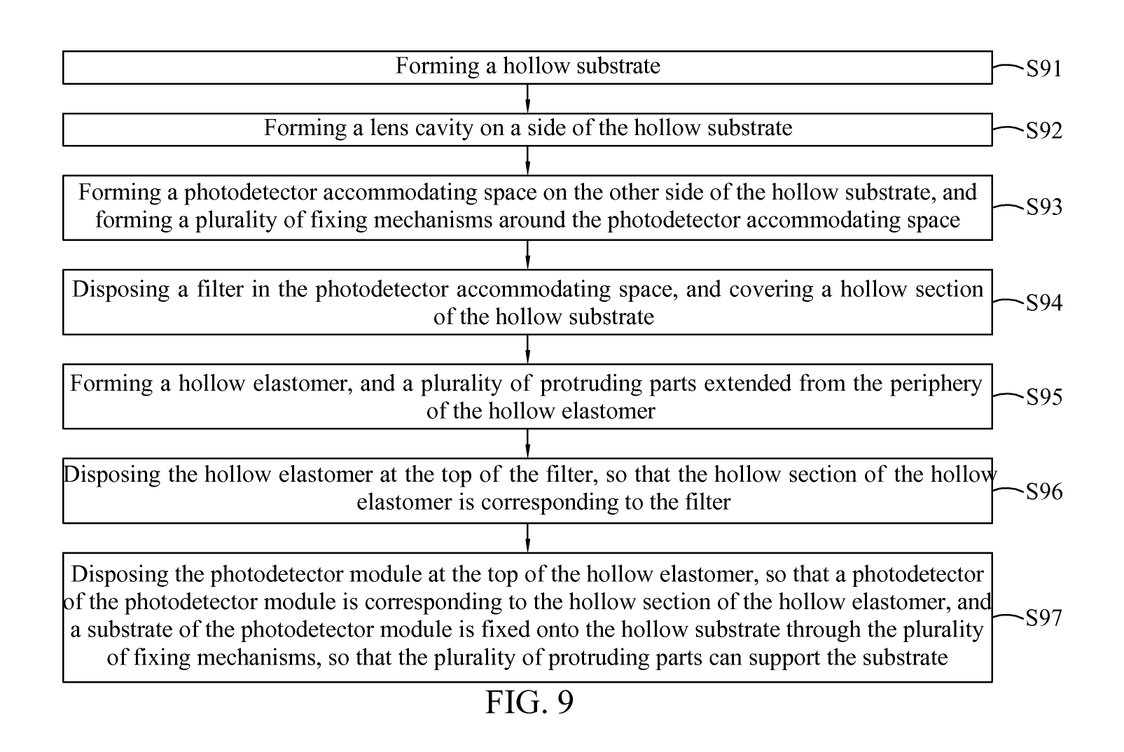

With reference to FIG. 9 for a flow chart of a method of manufacturing a lens holder of the present invention, the manufacturing method comprises the following steps.

S91: Form a hollow substrate.

S92: Form a lens cavity on a side of the hollow substrate.

S93: Form a photodetector accommodating space on the other side of the hollow substrate, and form a plurality of fixing mechanisms around the photodetector accommodating space.

S94: Dispose a filter in the photodetector accommodating space, and cover a hollow section of the hollow substrate.

S95: Form a hollow elastomer, and a plurality of protruding parts extended from the periphery of the hollow elastomer.

S96: Dispose the hollow elastomer at the top of the filter, so that the hollow section of the hollow elastomer corresponds to the filter.

S97: Dispose the photodetector module at the top of the hollow elastomer, so that a photodetector of the photodetector module corresponds to the hollow section of the hollow elastomer, and a substrate of the photodetector module is fixed onto the hollow substrate through the plurality of fixing mechanisms, so that the plurality of protruding parts can support the substrate.

In summation of the description above, the lens holder of the present invention no longer needs to add the washer and the spring in the lens holder, so that the production cost of the lens holder can be significantly reduced. In addition, the present invention no longer needs to use the UV glue to fix the spring in the lens holder to avoid technical issues occurred in the assembling process and facilitate reworking. Further the lens holder of the present invention uses a rubber washer with special structure to substitute the conventional washer and spring of the lens holder to simplify the alignment process. Since no washer is used, a higher accuracy can be achieved. Obviously, the present invention breaks through the prior art and achieves the improved effects, also complies with the patent application requirements, and thus is duly filed for patent application.

While the invention has been described by means of specific embodiments, numerous modifications and variations could be made thereto by those skilled in the art without departing from the scope and spirit of the invention set forth in the claims.

What is claimed is:

1. A lens holder, comprising:
a hollow substrate, having a lens cavity extended along a side of the hollow substrate, and a photodetector accommodating space extended from the other side of the hollow substrate opposite to the lens cavity, and a plurality of fixing mechanisms disposed around the photodetector accommodating space;
a filter, disposed in the photodetector accommodating space, and covered onto a hollow section of the hollow substrate;
a hollow elastomer, disposed at a top of the filter, and a hollow section of the hollow elastomer corresponding to the filter; and
a photodetector module, disposed at a top of the hollow elastomer, and comprising a photodetector and a substrate, and the photodetector being disposed at a position corresponding to the hollow section of the hollow elastomer, and the substrate being fixed onto the hollow substrate through the plurality of fixing mechanisms;
wherein, the hollow elastomer has a plurality of protruding parts extended from a periphery of the hollow elastomer, and the plurality of protruding parts supports the substrate, so that the hollow elastomer executes a tilt alignment of the photodetector directly.

2. The lens holder of claim 1, wherein a quantity of the fixing mechanisms is equal to a quantity of the protruding parts.

3. The lens holder of claim 2, wherein the quantity of the fixing mechanisms and the protruding parts is 3, 4 or 5.

4. The lens holder of claim 2, wherein the protruding part is disposed at a position corresponding to the fixing mechanism.

5. The lens holder of claim 1, wherein any two of the adjacent protruding parts is arranged with a constant distance apart.

6. The lens holder of claim 1, wherein the hollow elastomer is made of rubber.

7. A lens holder manufacturing method, comprises steps of:
forming a hollow substrate;
forming a lens cavity on a side of the hollow substrate;
forming a photodetector accommodating space on the other side of the hollow substrate, and forming a plurality of fixing mechanisms around the photodetector accommodating space;
disposing a filter in the photodetector accommodating space, and covering a hollow section of the hollow substrate;
forming a hollow elastomer, and the hollow elastomer having a plurality of protruding parts extended from a periphery of the hollow elastomer;
disposing the hollow elastomer to a top of the filter, and a hollow section of the hollow elastomer corresponding to the filter; and
disposing a photodetector module on a top of the hollow elastomer, and a photodetector of the photodetector module corresponding to the hollow section of the hollow elastomer, and fixing a substrate of the photodetector module onto the hollow substrate through the plurality of fixing mechanisms, such that the plurality of protruding parts supports the substrate.

8. The lens holder manufacturing method of claim 7, wherein a quantity of the fixing mechanisms is equal to a quantity of the protruding parts.

9. The lens holder manufacturing method of claim 8, wherein the quantity of the fixing mechanisms and the protruding parts is 3, 4 or 5.

10. The lens holder manufacturing method of claim 8, wherein the protruding part is disposed at a position corresponding to the fixing mechanism.

11. The lens holder manufacturing method of claim 7, wherein any two of the adjacent protruding parts is arranged with a constant distance apart.

12. An image capturing device, comprising a lens and a lens holder, and the lens holder comprising:
a hollow substrate, having a lens cavity extended along a side of the hollow substrate, and a photodetector accommodating space extended from the other side of the hollow substrate opposite to the lens cavity, and a plurality of fixing mechanisms disposed around the photodetector accommodating space, and the lens cavity being provided for accommodating the lens;
a filter, disposed in the photodetector accommodating space, and covered onto a hollow section of the hollow substrate;
a hollow elastomer, disposed at a top of the filter, and a hollow section of the hollow elastomer corresponding to the filter; and
a photodetector module, disposed at a top of the hollow elastomer, and comprising a photodetector and a substrate, and the photodetector being disposed at a position corresponding to the hollow section of the hollow elastomer, and the substrate being fixed onto the hollow substrate through the plurality of fixing mechanisms;
wherein, the hollow elastomer has a plurality of protruding parts extended from a periphery of the hollow elastomer, and the plurality of protruding parts supports the substrate, so that the hollow elastomer executes a tilt alignment of the photodetector directly.

13. The image capturing device of claim 12, wherein a quantity of the fixing mechanisms is equal to a quantity of the protruding parts.

14. The image capturing device of claim 13, wherein the quantity of the fixing mechanisms and the protruding parts is 3, 4 or 5.

15. The image capturing device of claim 13, wherein the protruding part is disposed at a position corresponding to the fixing mechanism.

16. The image capturing device of claim 12, wherein any two of the adjacent protruding parts is arranged with a constant distance apart.
